(19) United States
(12) Patent Application Publication
(10) Pub. No.: US 2008/0066296 A1
(43) Pub. Date: Mar. 20, 2008

(54) Method for manufacturing an electric heating mirror and the mirror thereof

(76) Inventors: Chung-kyun Shin, Bucheon-si (KR); Byoung-chan Kim, Namdong-gu (KR); Jae-joon Ryou, Siheung-si (KR)

Correspondence Address: RABIN & Berdo, PC, 1101 14TH STREET, NW, SUITE 500, WASHINGTON, DC, 20005, US

(21) Appl. No.: 11/984,272

(22) Filed: Nov. 15, 2007

Related U.S. Application Data
(62) Division of application No. 11/503,218, filed on Aug. 14, 2006.

(30) Foreign Application Priority Data
Mar. 24, 2006 (KR) 10-2006-0026748

(51) Int. Cl. H05B 3/84; H05K 3/10

(52) U.S. Cl. 29/611; 219/219; 29/846; 29/857

(57) ABSTRACT

There are provided a method for manufacturing an electric heating mirror and the mirror thereof. An electrode pattern is printed on a metal-coated surface of the mirror in which the metal-coated surface is formed on a rear surface of a glass plate, or printed on a rear surface of the glass plate of the mirror in which the metal-coated surface is formed on a front surface of the glass plate using a conductive paste. Thereafter, a current input terminal is connected to the electrode pattern in parallel after protecting the electrode pattern by a PTC paste. Alternatively, the current input terminal is connected to the electrode pattern in series after forming a passivation layer on the electrode pattern by any of printing, coating, and deposition process. According to the method, the manufacturing process is simplified and the manufacturing cost decreases. In addition, environmental pollutants are not produced at all and the durability of the plane heater is enhanced. Further, the electrode pattern is not damaged and thus, there is no flame during the heating operation of the plane heater.

### BACKGROUND OF THE INVENTION

1. Field of the Invention

The present invention relates to a variety of electric heating mirrors used as a side mirror for a vehicle, a heating mirror, or the like, and more particularly, to a method for manufacturing an electric heating mirror having a plane heater, and the mirror thereof.

2. Description of the Conventional

In general, an electric heating mirror used as a side mirror for a vehicle, a heating mirror, etc, is manufactured separately, and it melts or vaporizes frostwork or moisture formed on the surface of the mirror due to the heat generated by a plane heater attached on the backside of the heating mirror.

The plane heater which is formed in various kinds of heating mirrors is mainly classified into two types. One is a positive temperature coefficient (PTC) type plane heater including a PTC thermistor such as a carbon paste, a silver paste or the like, wherein the PTC type plane heater has a parallel connection scheme of a current input terminal. The other one is a NON-PTC type plane heater which does not include the PTC thermistor and has a serial connection scheme of a current input terminal. A conventional plane heater is developed as a kind of the PTC type plane heaters, which is disclosed in Korean Patent No. 10-0411401.

The conventional plane heater disclosed in Korean Patent No. 10-0411401 is manufactured by a method including: preparing an insulating substrate by stacking an aluminum foil on a PET sheet by vacuum deposition process; printing an etching resist of a predetermined pattern on the aluminum foil of the insulating substrate; spraying etching agent to etch the aluminum foil which is not covered with the printed portion of the etching resist; rinsing out the etching resist and the etching agent using alkali aqueous solution; printing a carbon paste of a predetermined shape, wherein the carbon paste is a kind of the PTC thermistor; and connecting a current input terminal to an electrode layer of the aluminum foil in parallel.

Meanwhile, if the printing process using the carbon paste is omitted in the process of manufacturing the conventional plane heater disclosed in Korean Patent No. 10-0411401, and the current input terminal is connected to the electrode of the aluminum foil in series after a passivation layer of polyester is printed on the aluminum foil and dried, it is possible to manufacture a NON-PTC type plane heater.

In the conventional plane heater manufactured by the above process, an adhesive layer is formed by attaching a double sided adhesive tape or coating an adhesive agent on the insulating substrate or the carbon paste of the PTC thermistor, in which a release paper is attached on the adhesive layer. Actually, if forming such a plane heater on the backside of the mirror where a metal-coated surface such as nickel, aluminum, chromium, or the like is formed, a variety of electric heating mirrors are manufactured, which are used as the side mirror for vehicles, the heating mirror, etc.

However, in the method for manufacturing the conventional plane heater, the etching agent such as hydrochloric acid is used for etching the etching resist or the aluminum foil and further an alkali aqueous solution such as sodium hydroxide aqueous solution is used for removing the etching resist and the etching agent, which results in increasing the manufacturing cost. In particular, environmentally harmful materials such as aluminum corroded during the manufacturing process, hydrochloric acid, sodium hydroxide, etc, are produced inevitably, which causes environmental pollution.

Moreover, there is a shortcoming in that the durability of the plane heater is degraded due to hydrochloric acid and alkaline components remaining in the plane heater. Particularly, since the electrode pattern formed of the aluminum foil is often partially damaged during the etching process, there is also a failing that a flame may happen during the heating operation of the plane heater.

Therefore, a conventional electric heating mirror having the conventional plane heater manufactured by the above method also has all the problems or shortcomings caused by the conventional plane heater as well.

### SUMMARY OF THE INVENTION

An object of the present invention is to provide a method for manufacturing an electric heating mirror in which a positive temperature coefficient (PTC) paste of a predetermined shape is printed on both an electrode pattern and a region of a top surface of an insulating layer where the electrode pattern is not formed after the electrode pattern formed of a conductive paste is directly printed on the insulating layer formed on a metal-coated surface of the mirror, and thereafter, a current input terminal is connected to the electrode pattern in parallel, wherein the metal-coated surface is formed on a rear surface of a glass plate.

Another object of the present invention is to provide a method for manufacturing an electric heating mirror in which a PTC paste of a predetermined shape is printed on both an electrode pattern and a region of a rear surface of a glass plate where the electrode pattern is not formed after the electrode pattern formed of a conductive paste is directly printed on the rear surface of the glass plate of the mirror, and thereafter, a current input terminal is connected to the electrode pattern in parallel, wherein a metal-coated surface is formed on a front surface of the glass plate.

A further object of the present invention is to provide a method for manufacturing an electric heating mirror in which a PTC paste of a predetermined shape is printed on both an electrode pattern and a region of a top surface of an insulating layer where the electrode pattern is not formed after the electrode pattern is plated or deposited on the top surface of the insulating layer using water-soluble metalize resist ink, and thereafter, a current input terminal is connected to the electrode pattern in parallel, wherein the insulating layer is formed on a passivation layer deposited on a metal-coated surface of the mirror in which the metal-coated surface is formed on a rear surface of a glass plate.

A further object of the present invention is to provide a method for manufacturing an electric heating mirror in which a PTC paste of a predetermined shape is printed on both an electrode pattern and a region of a top surface of an insulating layer where the electrode pattern is not formed after the electrode pattern is plated or deposited on the top surface of the insulating layer using a protection jig, and thereafter, a current input terminal is connected to the electrode pattern in parallel, wherein the insulating layer is formed on a passivation layer deposited on a metal-coated surface of the mirror in which the metal-coated surface is formed on a rear surface of a glass plate.

A further object of the present invention is to provide a method for manufacturing an electric heating mirror in which a passivation layer is formed on both an electrode pattern and a region of a top surface of an insulating layer where the electrode pattern is not formed using printing, coating or deposition process after the electrode pattern formed of a conductive paste is directly printed on the insulating layer formed on a metal-coated surface of the mirror, and thereafter, a current input terminal is connected to the electrode pattern in series, wherein the metal-coated surface is formed on a rear surface of a glass plate.

A further object of the present invention is to provide a method for manufacturing an electric heating mirror in which a passivation layer is formed on both an electrode pattern and a region of a rear surface of a glass plate where the electrode pattern is not formed using printing, coating or deposition process after the electrode pattern formed of a conductive paste is directly printed on the rear surface of the glass plate, and thereafter, a current input terminal is connected to the electrode pattern in series, wherein a metal-coated surface is formed on a front surface of a glass plate.

A further object of the present invention is to provide a method for manufacturing an electric heating mirror in which a passivation layer is formed on both an electrode pattern and a region of a top surface of an insulating layer where the electrode pattern is not formed after the electrode pattern is plated or deposited on the top surface of the insulating layer using water-soluble metalize resist ink, and thereafter, a current input terminal is connected to the electrode pattern in series, wherein the insulating layer is formed on the passivation layer deposited on a metal-coated surface of the mirror in which the metal-coated surface is formed on a rear surface of a glass plate.

A further object of the present invention is to provide a method for manufacturing an electric heating mirror in which a passivation layer is formed on both an electrode pattern and a region of a top surface of an insulating layer where the electrode pattern is not formed after the electrode pattern is plated or deposited on the top surface of the insulating layer using a protection jig, and thereafter, a current input terminal is connected to the electrode pattern in series, wherein the insulating layer is formed on the passivation layer deposited on a metal-coated surface of the mirror in which the metal-coated surface is formed on a rear surface of a glass plate.

A further object of the present invention is to provide the mirror fabricated by the aforementioned methods for manufacturing the electric heating mirror.

According to an aspect of the present invention, there is provided a method for manufacturing an electric heating mirror, the method including: forming an insulating layer on a metal-coated surface of a mirror in which the metal-coated surface is formed on a rear surface of a glass plate; printing an electrode pattern of a predetermined shape on the insulating layer using a conductive paste, and drying it; printing a positive temperature coefficient (PTC) paste of a predetermined shape on both the electrode pattern and a region of the top surface of the insulating layer where the electrode pattern is not formed; and connecting a current input terminal to the electrode pattern in parallel using a conductive adhesive agent.

According to another aspect of the present invention, there is provided a method for manufacturing an electric heating mirror, the method including: printing an electrode pattern of a predetermined shape on a rear surface of a glass plate of a mirror in which a metal-coated surface is formed on a front surface of the glass plate using a conductive paste, and drying it; printing a PTC paste of a predetermined shape on both the electrode pattern and a region of the rear surface of the glass plate where the electrode pattern is not formed, and drying it; and connecting a current input terminal to the electrode pattern in parallel using a conductive adhesive agent.

According to a further aspect of the present invention, there is provided a method for manufacturing an electric heating mirror, the method including: depositing a passivation layer on a metal-coated surface of a mirror in which the metal-coated surface is formed on a rear surface of a glass plate; forming an insulating layer on the passivation layer; printing a predetermined cover layer pattern on the top surface of the insulating layer using water-soluble metalize resist ink, and drying it; forming a predetermined electrode pattern on a region of the insulating layer not covered with the cover layer pattern by plating or depositing any of copper, silver and gold; drying the electrode pattern after rinsing out the cover layer pattern by hot water; printing a PTC paste of a predetermined shape on both the electrode pattern and a region of the insulating layer where the electrode pattern is not formed, and drying it; and connecting a current input terminal to the electrode pattern in parallel using a conductive adhesive agent.

According to a further aspect of the present invention, there is provided a method for manufacturing an electric heating mirror, the method including: depositing a passivation layer on a metal-coated surface of a mirror in which the metal-coated surface is formed on a rear surface of a glass plate; forming an insulating layer on the passivation layer; disposing a protection jig on the top surface of the insulating layer, wherein the protection jig partially covers the top surface of the insulating layer with a predetermined cover layer pattern; forming a predetermined electrode pattern on a region of the insulating layer not covered with the cover layer pattern by plating or depositing any of copper, silver and gold; removing the protection jig from the insulating layer; printing a PTC paste of a predetermined shape on both the electrode pattern and a region of the insulating layer where the electrode pattern is not formed, and drying it; and connecting a current input terminal to the electrode pattern in parallel using a conductive adhesive agent.

According to a further aspect of the present invention, there is provided a method for manufacturing an electric heating mirror, the method including: forming an insulating layer on a metal-coated surface of a mirror in which the metal-coated surface is formed on a rear surface of a glass plate; printing an electrode pattern of a predetermined shape on the insulating layer using a conductive paste, and drying it; forming a passivation layer on both the electrode pattern and a region of the insulating layer where the electrode pattern is not formed by any of printing, coating and deposition process; and connecting a current input terminal to the electrode pattern in series using a conductive adhesive agent.

According to a further aspect of the present invention, there is provided a method for manufacturing an electric heating mirror, the method including: printing an electrode pattern of a predetermined shape on a rear surface of a glass plate of a mirror, and drying it, wherein a metal-coated surface is formed on a front surface of the glass plate; forming a passivation layer on both the electrode pattern and a region of a rear surface of the glass plate where the electrode pattern is not formed by any of printing, coating and deposition process; and connecting a current input terminal to the electrode pattern in series using a conductive adhesive agent.

According to a further aspect of the present invention, there is provided a method for manufacturing an electric heating mirror, the method including: depositing a passivation layer on a metal-coated surface of a mirror in which the metal-coated surface is formed on a rear surface of a glass plate; forming an insulating layer on the passivation layer; printing a predetermined cover layer pattern on the top surface of the insulating layer using water-soluble metalize resist ink, and drying it; forming a predetermined electrode pattern on a region of the insulating layer not covered with the cover layer pattern by plating or depositing any of copper, silver and gold; drying the electrode pattern after rinsing out the cover layer pattern by hot water; printing/drying or depositing a passivation layer on both the electrode pattern and a region of the insulating layer where the electrode pattern is not formed; and connecting a current input terminal to the electrode pattern in series using a conductive adhesive agent.

According to a further aspect of the present invention, there is provided a method for manufacturing an electric heating mirror, the method including: depositing a passivation layer on a metal-coated surface of a mirror in which the metal-coated surface is formed on a rear surface of a glass plate; forming an insulating layer on the passivation layer; disposing a protection jig on the top surface of the insulating layer, wherein the protection jig partially covers the top surface of the insulating layer with the cover layer pattern; forming a predetermined electrode pattern on a region of the insulating layer not covered with the cover layer pattern by plating or depositing any of copper, silver and gold; removing the protection jig from the insulating layer; printing/drying or depositing a passivation layer on both the electrode pattern and a region of the insulating layer where the electrode pattern is not formed; and connecting a current input terminal to the electrode pattern in series using a conductive adhesive agent.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross-sectional view illustrating a method for manufacturing a positive temperature coefficient (PTC) type electric heating mirror according to a first embodiment of the present invention;

FIG. 2 is a plan view of the PTC type heating mirror according to the first embodiment of the present invention;

FIG. 3 is a cross-sectional view illustrating a method for manufacturing a PTC type electric heating mirror according to a second embodiment of the present invention;

FIG. 4 is a plan view of the PTC type heating mirror according to the second embodiment of the present invention;

FIG. 5 is a cross-sectional view illustrating a method for manufacturing a PTC type electric heating mirror according to third and fourth embodiments of the present invention;

FIG. 6 is a plan view of the PTC type heating mirror according to the third and fourth embodiments of the present invention;

FIG. 7 is a cross-sectional view illustrating a method for manufacturing a NON-PTC type electric heating mirror according to a fifth embodiment of the present invention;

FIG. 8 is a plan view of the NON-PTC type heating mirror according to the fifth embodiment of the present invention;

FIG. 9 is a cross-sectional view illustrating a method for manufacturing a NON-PTC type electric heating mirror according to a sixth embodiment of the present invention;

FIG. 10 is a plan view of the NON-PTC type heating mirror according to the sixth embodiment of the present invention;

FIG. 11 is a cross-sectional view illustrating a method for manufacturing a NON-PTC type electric heating mirror according to seventh and eighth embodiments of the present invention; and

FIG. 12 is a plan view of the NON-PTC type heating mirror according to the seventh and eighth embodiments of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

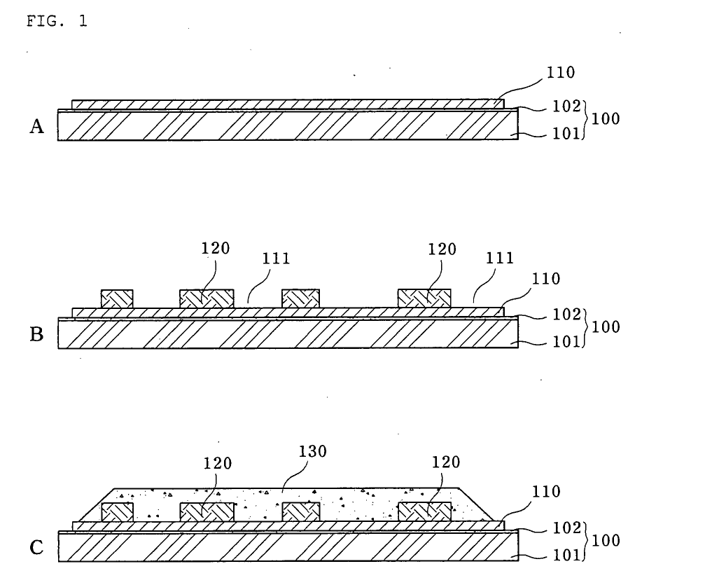

FIG. 1 is a cross-sectional view illustrating a method for manufacturing a positive temperature coefficient (PTC) type electric heating mirror according to a first embodiment of the present invention. This method is applied to a mirror 100 in which a metal-coated surface 102 is formed on a rear surface of a glass plate 101.

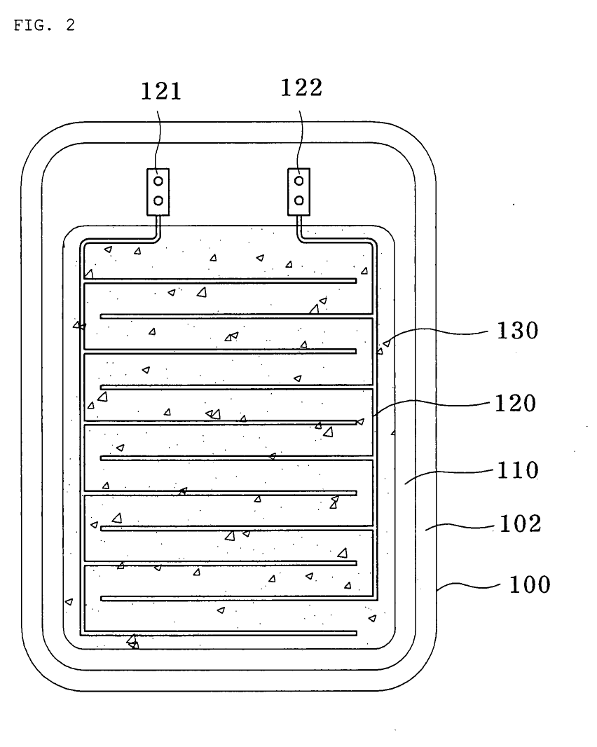

Referring to FIGS. 1 and 2, first of all, an insulating layer 110 of typical epoxy-based insulating ink is formed on the metal-coated surface 102 of the mirror 100 having predetermined size and shape which meets the standard requirement, wherein the metal-coated surface 102 is formed of nickel, aluminum, chromium, etc (see A of FIG. 1).

After forming the insulating layer 110, an electrode pattern 120 having a specific shape is directly printed on the top surface of the insulating layer 110 using a conductive paste such as carbon paste, aluminum paste, copper paste, silver paste, gold paste, or the like, and thereafter, it is dried (see B of FIG. 1).

During this printing and drying process, the electrode pattern 120 may be formed such that it has various shapes. In particular, the top surface of the insulating layer 110 is divided into two regions, of which one is a region where the electrode pattern 120 is formed and the other is a region 111 where the electrode pattern 120 is not formed.

After completely drying the electrode pattern 120 of the predetermined shape on the insulating layer 110, a PTC paste 130 acting as a thermistor is printed into a specific shape on both the electrode pattern 120 and the region 111 of the top surface of the insulating layer 110 where the electrode pattern 120 is not formed, and then it is dried. Therefore, an electric heating mirror without a current input terminal is manufactured (see C of FIG. 1).

Referring to FIG. 2, after manufacturing the electric heating mirror which does not have the current input terminal for supplying a power, a current input terminal 121 and 122 is connected to a predetermined portion of the electrode pattern 120 in parallel using a conductive adhesive agent, thereby completing the PTC type electric heating mirror 100 in which the metal-coated surface 102 is formed on the rear surface of the glass plate 101 and a heating unit is integrally formed on the rear surface of the metal-coated surface 102.

For example, if the PTC type electric heating mirror 100 is used as a side mirror for vehicles, the electric heating mirror may constitute a side mirror assembly in company with a holder of the side mirror for vehicles through an insert molding process.

Herebelow, a second embodiment of the present invention will be illustrated in detail with reference to the accompanying drawings.

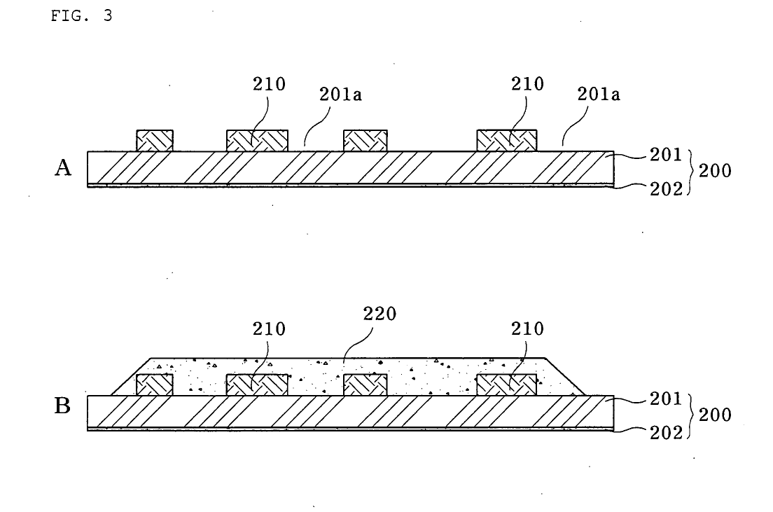

FIG. 3 is a cross-sectional view illustrating a method for manufacturing a PTC type electric heating mirror according to a second embodiment of the present invention. This method is applied to a mirror 200 in which a metal-coated surface 202 is formed on a front surface of a glass plate 201.

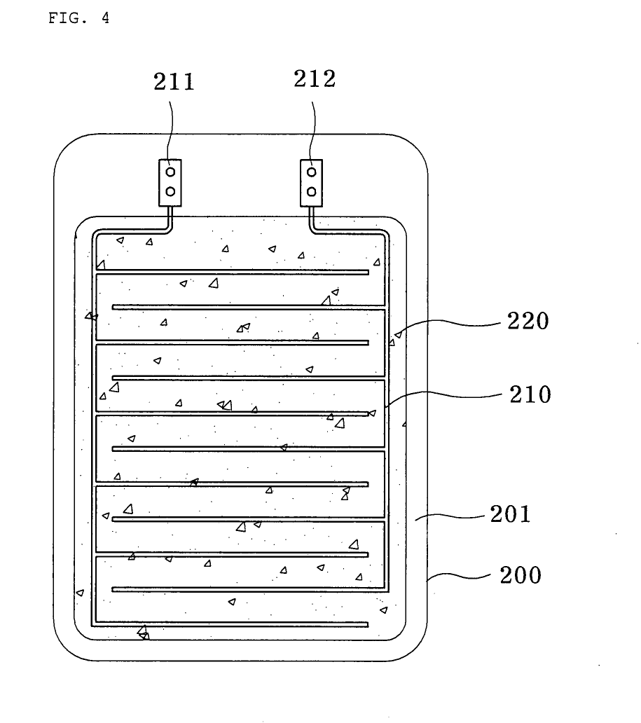

Referring to FIGS. 3 and 4, first of all, an electrode pattern 210 with a specific shape is directly printed on the rear surface of the glass plate 201 of the mirror 200 using a conductive paste such as carbon paste, aluminum paste, copper paste, silver paste, gold paste, or the like, and thereafter, it is dried (see A of FIG. 3). Herein, the mirror 200 is prepared in advance such that it has predetermined size and shape according to the standard requirement.

During this printing and drying process, the glass plate 201 acts as the insulating layer 111 of FIG. 1 and the electrode pattern 210 of the second embodiment may also be formed such that it has various shapes. In particular, the rear surface of the glass plate 201 is divided into two regions, of which one is a region where the electrode pattern 210 is formed and the other is a region 201a where the electrode pattern 210 is not formed.

After completely drying the electrode pattern 210 of the predetermined shape, a PTC paste 220 acting as a thermistor is printed into a specific shape on both the electrode pattern 210 and the region 201a of the rear surface of the glass plate 201 where the electrode pattern 210 is not formed, and then it is dried. Therefore, an electric heating mirror without a current input terminal is manufactured (see B of FIG. 3).

Referring to FIG. 4, after manufacturing the electric heating mirror which does not have the current input terminal for supplying a power, a current input terminal 211 and 212 is connected to a predetermined portion of the electrode pattern 210 in parallel using a conductive adhesive agent, thereby completing the PTC type electric heating mirror 200 in which the metal-coated surface 202 is formed on the front surface of the glass plate 201 and a heating unit is integrally formed on the rear surface of the glass plate 201.

For instance, if the PTC type electric heating mirror 200 is used as a side mirror for vehicles, the electric heating mirror may constitute a side mirror assembly in company with a holder of the side mirror for vehicles through an insert molding process.

Herebelow, a third embodiment of the present invention will be illustrated in detail with reference to the accompanying drawings.

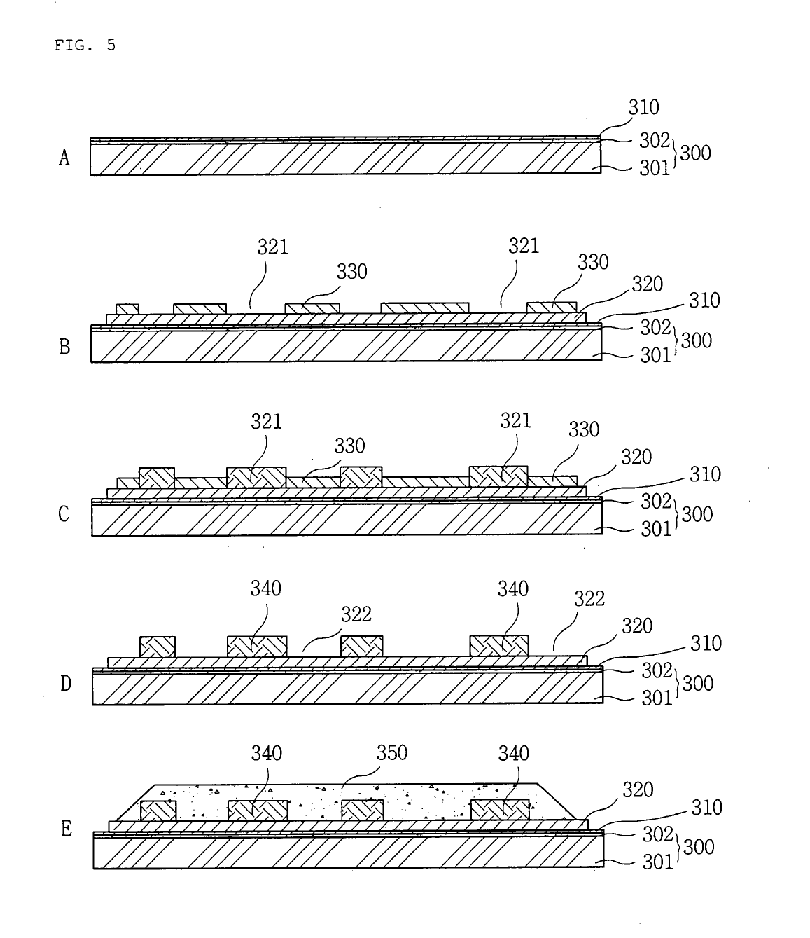

FIG. 5 is a cross-sectional view illustrating a method for manufacturing a PTC type electric heating mirror according to third and fourth embodiments of the present invention. This method is applied to a mirror 300 in which a metal-coated surface 302 is formed on a rear surface of a glass plate 301.

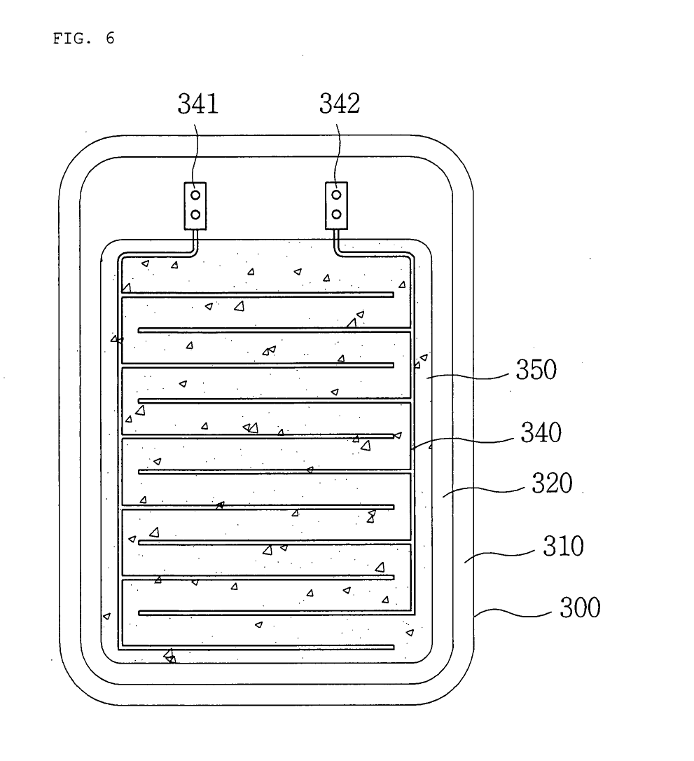

Referring to FIGS. 5 and 6, to being with, a passivation layer 310, which is formed of silicon oxide, titanium oxide and so forth, is formed on the metal-coated surface 302 of the mirror 300 having predetermined size and shape which meets the standard requirement, wherein the metal-coated surface 302 is formed of nickel, aluminum, chromium, etc (see A of FIG. 5). In this case, the passivation layer 310 may be formed by various methods such as deposition, spray, printing, or the like.

After forming the passivation layer 310 over the mirror 300, an insulating layer 320 of typical epoxy based insulating ink is formed on the passivation layer 310. Thereafter, a specific cover layer pattern 330 which partially covers the top surface of the insulating layer 320 is printed on the top surface of the insulating layer 320 using water-soluble metalize resist ink, and then it is dried (see B of FIG. 5). Herein, the insulating layer 320 may be formed by various methods such as printing, spray, or the like. In addition, it is preferable to use KP-1000™ (made by KTS Co., Ltd., in Korea) as the water-soluble metalize resist ink for this process.

After printing the cover layer pattern 330 on the top surface of the insulating layer 320, a specific electrode pattern 340 is formed on a predetermined region 321 of the insulating layer 320 not covered with the cover layer pattern 330 by plating or depositing any of copper, silver and gold (see C of FIG. 5). The shape of the electrode pattern 340 is determined by the cover layer pattern 330 formed of the water-soluble metalize resist ink, wherein the cover layer pattern 330 may be variously modified for the sake of manufacturing convenience.

After forming the specific electrode pattern 340, the cover layer pattern 330 formed of the water-soluble metalize resist ink is rinsed out by hot water, and then the electrode pattern 340 is dried (see D of FIG. 5). Accordingly, the top surface of the insulating layer 320 is divided into two regions, of which one is a region where the electrode pattern 340 is formed and the other is a region 322 where the cover layer pattern 330 is removed.

After completely drying the electrode pattern 340, a PTC paste 350 acting as a thermistor is printed into a predetermined shape on both the electrode pattern 340 and the region of the insulating layer 320 where the electrode pattern 340 is not formed, i.e., the region 322 where the cover layer pattern 330 is removed. Afterwards, the resultant structure is dried thereby manufacturing the electric heating mirror without a current input terminal (see E of FIG. 5).

Finally, referring to FIG. 6, a current input terminal 341 and 342 is connected to a predetermined portion of the electrode pattern 340 in parallel using a conductive adhesive agent, thereby completing the PTC type electric heating mirror 300 in which the metal-coated surface 302 is formed on the rear surface of the glass plate 301 and a heating unit is integrally formed on the metal-coated surface 302.

For example, if the PTC type electric heating mirror 300 is used as a side mirror for vehicles, the electric heating mirror may constitute a side mirror assembly in company with a holder of the side mirror for vehicles through an insert molding process.

Herebelow, a fourth embodiment of the present invention will be also illustrated in detail with reference to FIGS. 5 and 6.

Comparing a method for manufacturing a PTC type electric heating mirror according to the fourth embodiment with the method for manufacturing the PTC type electric heating mirror according to the third embodiment as illustrated in FIGS. 5 and 6, there are differences in forming the cover layer pattern 330 and the electrode pattern 340.

To begin with, as illustrated in A and B of FIG. 5, after forming the insulating layer 320 on the passivation layer 310 which is formed over the mirror 300, a protection jig (not shown) is disposed on the top surface of the insulating layer 320 so as to partially cover the top surface of the insulating layer 320 with a cover layer pattern 330 which is identical in shape to the cover layer pattern 330 of the third embodiment. Accordingly, it is possible to form the cover layer pattern on the top surface of the insulating layer 320 without using the water-soluble metalize resist ink, which is significantly different from the third embodiment.

After forming the cover layer pattern 330 on the predetermined portion of the insulating layer 320 by means of the protection jig, any of copper, silver and gold is plated or deposited on a predetermined region 321 of the insulating layer 320 which is not covered with cover layer pattern 330 to thereby form a specific electrode pattern 340 (see C of FIG. 5). During this process, the shape of the electrode pattern 340 is determined by cover layer pattern 330 formed by the protection jig, wherein the cover layer pattern 330 may be variously modified for the sake of manufacturing convenience.

After forming the specific electrode pattern 340, the protection jig is removed from the insulating layer 320 (see D of FIG. 5). Thus, the top surface of the insulating layer 320 is divided into two regions, of which one is a region where the electrode pattern 340 is formed and the other is the region 322 where the electrode pattern 340 is not formed.

Thereafter, a PTC paste 350 acting as a thermistor is printed into a predetermined shape on both the electrode pattern 340 and the region 322 of the insulating layer 320 where the electrode pattern 340 is not formed. Afterwards, the resultant structure is dried thereby manufacturing the electric heating mirror without a current input terminal (see E of FIG. 5).

Finally, referring to FIG. 6, a current input terminal 341 and 342 is connected to a predetermined portion of the electrode pattern 340 in parallel using a conductive adhesive agent, thereby completing the PTC type electric heating mirror 300 in which the metal-coated surface 302 is formed on the rear surface of the glass plate 301 and a heating unit is integrally formed on the metal-coated surface 302.

For instance, if the PTC type electric heating mirror 300 is used as a side mirror for vehicles, the electric heating mirror may constitute a side mirror assembly in company with a holder of the side mirror for vehicles through an insert molding process.

Herebelow, a fifth embodiment of the present invention will be illustrated in detail with reference to the accompanying drawings.

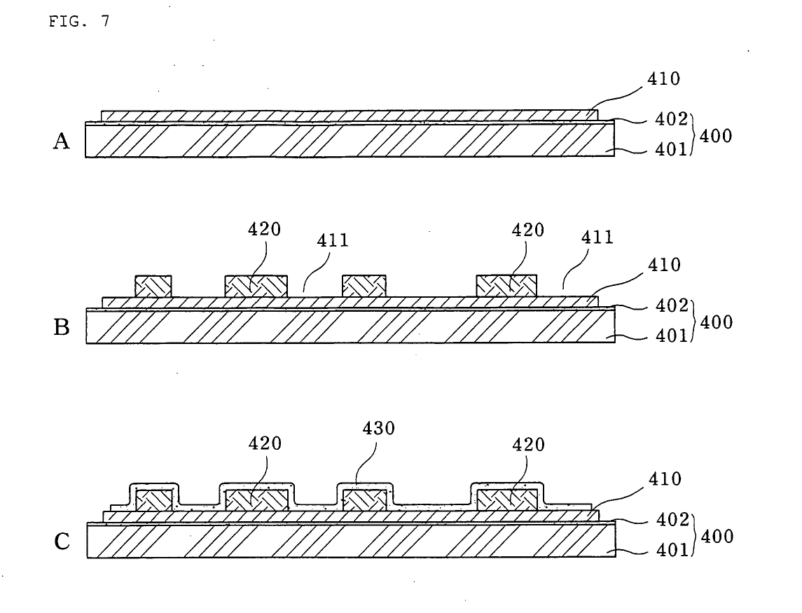

FIG. 7 is a cross-sectional view illustrating a method for manufacturing a NON-PTC type electric heating mirror according to a fifth embodiment of the present invention. This method is applied to a mirror 400 in which a metal-coated surface 402 is formed on the rear surface of a glass plate 401.

In comparison of the fifth embodiment with the first and second embodiments, it is different in that a serial connection scheme of a current input terminal is employed without using the PTC paste 130 and 220.

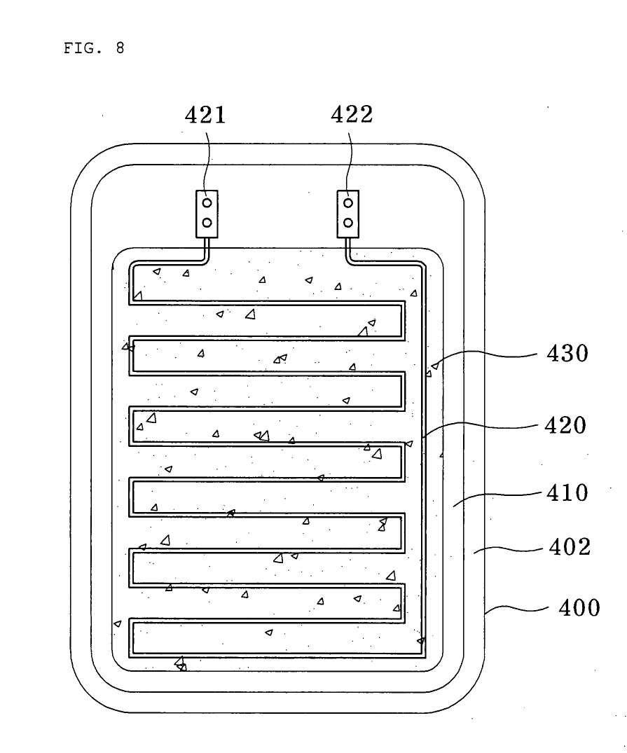

Referring to FIGS. 7 and 8, first of all, an insulating layer 410 of typical epoxy based insulating ink is formed on the metal-coated surface 402 of the mirror 400 having predetermined size and shape which meets the standard requirement, wherein the metal-coated surface 402 is formed of nickel, aluminum, chromium, etc (see A of FIG. 7).

After forming the insulating layer 410, an electrode pattern 420 with a specific shape is directly printed on the top surface of the insulating layer 410 using a conductive paste such as carbon paste, aluminum paste, copper paste, silver paste, gold paste, or the like, and thereafter, it is dried (see B of FIG. 7).

During this printing and drying process, the electrode pattern 420 may be formed such that it has various shapes. In particular, the top surface of the insulating layer 410 is divided into two regions, of which one is a region where the electrode pattern 420 is formed and the other is a region 411 where the electrode pattern 420 is not formed.

After completely drying the electrode pattern 420 of the predetermined shape, a passivation layer 430 of polyester or the like is printed on both the electrode pattern 420 and the region 411 of the top surface of the insulating layer 410 where the electrode pattern 420 is not formed, and then it is dried. Therefore, an electric heating mirror without a current input terminal is manufactured (see C of FIG. 7).

Referring to FIG. 8, after manufacturing the electric heating mirror without the current input terminal, a current input terminal 421 and 422 is connected to a predetermined portion of the electrode pattern 420 in series using a conductive adhesive agent, thereby completing the NON-PTC type electric heating mirror 400 in which the metal-coated surface 402 is formed on the rear surface of the glass plate 401 and a heating unit is integrally formed on the rear surface of the metal-coated surface 402.

For example, if the NON-PTC type electric heating mirror 400 is used as a side mirror for vehicles, the electric heating mirror may constitute a side mirror assembly in company with a holder of the side mirror for vehicles through an insert molding process.

Herebelow, a sixth embodiment of the present invention will be illustrated in detail with reference to the accompanying drawings.

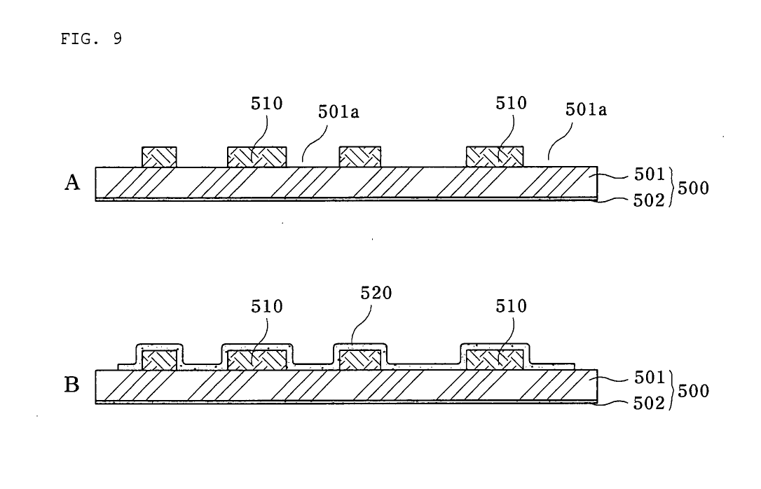

FIG. 9 is a cross-sectional view illustrating a method for manufacturing a NON-PTC type electric heating mirror according to a sixth embodiment of the present invention. This method is applied to a mirror 500 in which a metal-coated surface 502 is formed on the front surface of a glass plate 501.

In comparison of the sixth embodiment with the first and second embodiments, it is different in that a serial connection scheme of a current input terminal is employed without using the PTC paste 130 and 220.

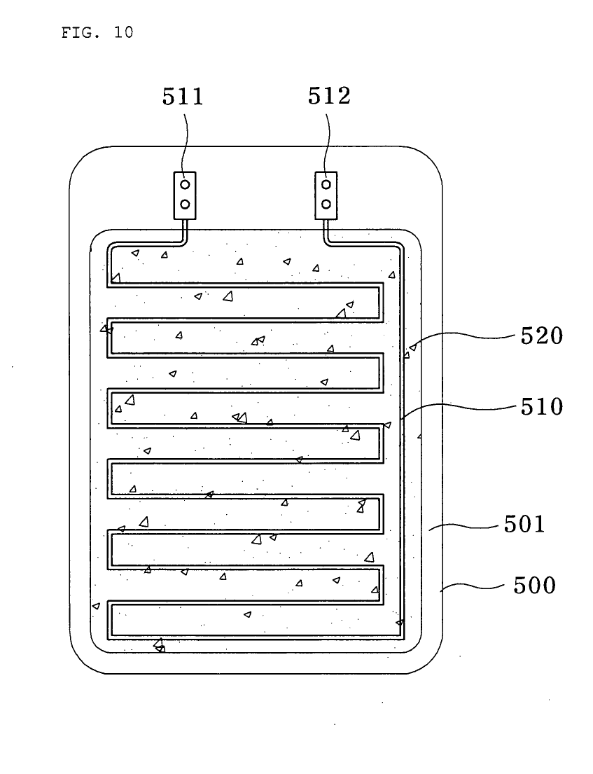

Referring to FIGS. 9 and 10, first of all, an electrode pattern 510 with a specific shape is directly printed on the rear surface of the glass plate 501 of the mirror 500 having predetermined size and shape which meets the required standard using a conductive paste such as carbon paste, aluminum paste, copper paste, silver paste, gold paste, or the like and, thereafter, it is dried (see A of FIG. 9).

During this printing and drying process, the glass plate 501 acts as the insulating layer 410 of FIG. 7, and the electrode pattern 510 of the sixth embodiment may also be formed such that it has various shapes. In particular, the rear surface of the glass plate 501 is divided into two regions, of which one is a region where the electrode pattern 510 is formed and the other is a region 501a where the electrode pattern 510 is not formed.

After completely drying the electrode pattern 510 with the predetermined shape, a passivation layer 520 of polyester or the like is printed on both the electrode pattern 510 and the region 501a of the rear surface of the glass plate 501 where the electrode pattern 510 is not formed, and then it is dried. Therefore, an electric heating mirror without a current input terminal is manufactured (see B of FIG. 9).

Referring to FIG. 10, after manufacturing the electric heating mirror without the current input terminal, a current input terminal 511 and 512 is connected to a predetermined portion of the electrode pattern 510 in series using a conductive adhesive agent, thereby completing the NON-PTC type electric heating mirror 500 in which the metal-coated surface 502 is formed on the front surface of the glass plate 501 and a heating unit is integrally formed on the rear surface of the glass plate 501.

For instance, if the NON-PTC type electric heating mirror 500 is used as a side mirror for vehicles, the electric heating mirror may constitute a side mirror assembly in company with a holder of the side mirror for vehicles through an insert molding process.

Herebelow, a seventh embodiment of the present invention will be illustrated in detail with reference to the accompanying drawings.

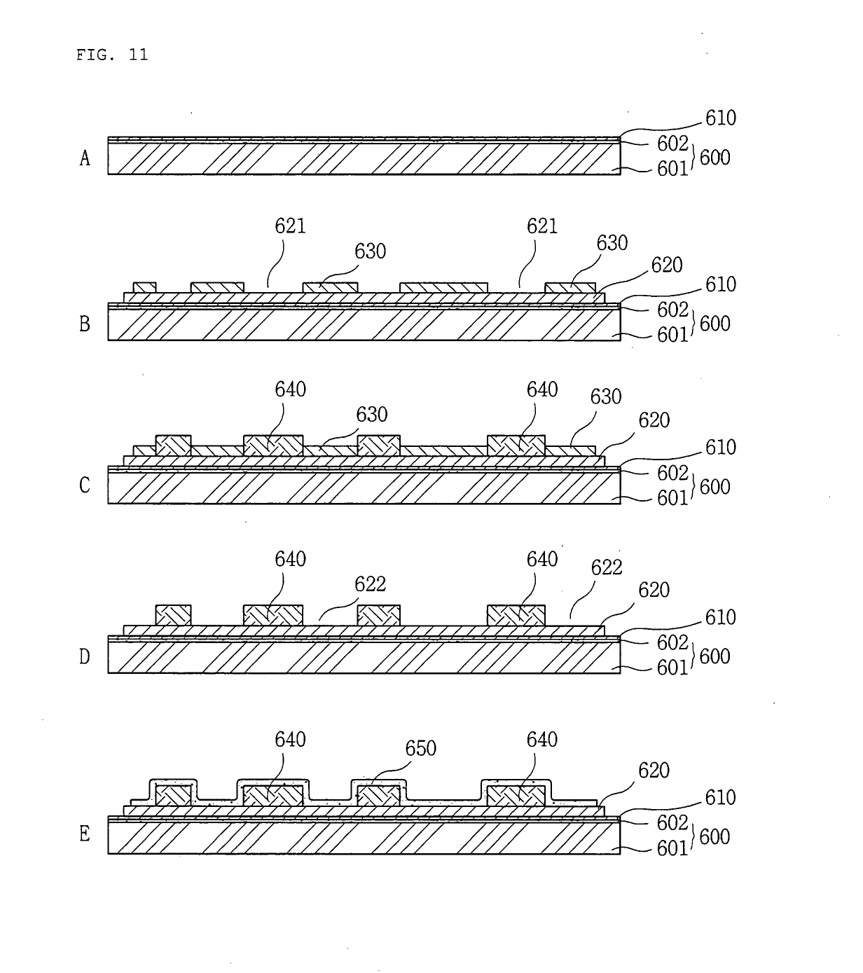

FIG. 11 is a cross-sectional view illustrating a method for manufacturing a NON-PTC type electric heating mirror according to seventh and eighth embodiments of the present invention. This method is applied to a mirror 600 in which a metal-coated surface 602 is formed on the rear surface of a glass plate 601.

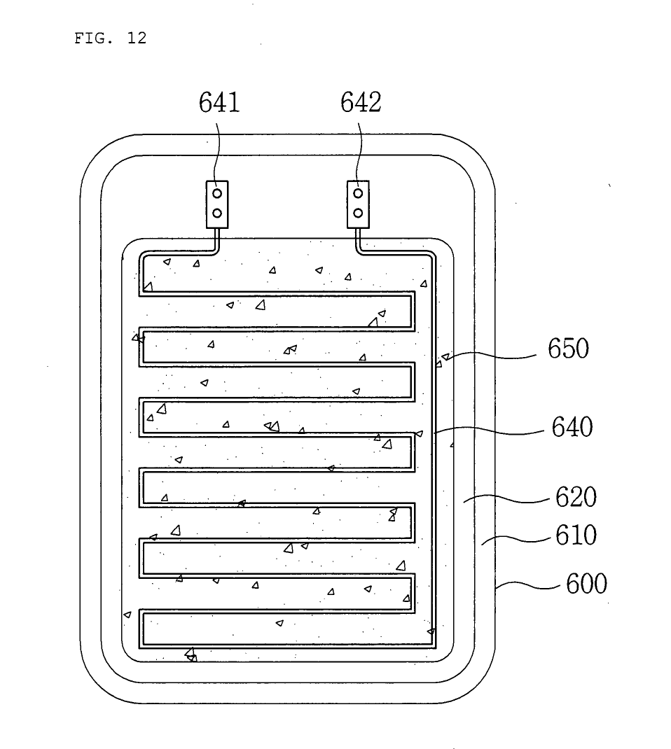

Referring to FIGS. 11 and 12, to being with, a passivation layer 610, which is formed of silicon oxide, titanium oxide and so forth, is formed on the metal-coated surface 602 of the mirror 600 having predetermined size and shape according to the standard requirement, wherein the metal-coated surface 602 is formed of nickel, aluminum, chromium, etc (see A of FIG. 11). In this case, the passivation layer 610 may be formed by various methods such as deposition, spray, printing, or the like.

After forming the passivation layer 610 over the mirror 600, an insulating layer 620 of typical epoxy based insulating ink is formed on the passivation layer 610. Thereafter, a specific cover layer pattern 630 which partially covers the top surface of the insulating layer 620 is printed on the top surface of the insulating layer 620 using water-soluble metalize resist ink and then it is dried (see B of FIG. 11). Herein, the insulating layer 620 may be formed by various methods such as printing, spray, or the like. In addition, it is preferable to use KP-1000™ (made by KTS Co., Ltd., in Korea) as the water-soluble metalize resist ink for this process.

After printing the cover layer pattern 630 on the top surface of the insulating layer 620, a specific electrode pattern 640 is formed on a predetermined region 621 of the insulating layer 630 not covered with the cover layer pattern 630 by plating or depositing any of copper, silver and gold on a region 21 (see C of FIG. 11). The shape of the electrode pattern 640 is determined by the cover layer pattern 630 formed of the water-soluble metalize resist ink, in which the cover layer pattern 630 may be variously modified for the sake of manufacturing convenience.

After forming the specific electrode pattern 640, the cover layer pattern 630 formed of the water-soluble metalize resist ink is rinsed out by hot water, and then the electrode pattern 640 is dried (see D of FIG. 11). Accordingly, the top surface of the insulating layer 620 is divided into a region where the electrode pattern 640 is formed and a region 622 where the cover layer pattern 630 is removed.

After completely drying the electrode pattern 640, a passivation layer of polyester or the like is printed/dried or deposited on both the electrode pattern 640 and the region of the insulating layer 620 where the electrode pattern 640 is not formed, i.e., the region 622 where the cover layer pattern 630 is removed. Afterwards, the resultant structure is dried thereby manufacturing the electric heating mirror without a current input terminal (see E of FIG. 11).

Finally, referring to FIG. 12, a current input terminal 641 and 642 is connected to a predetermined portion of the electrode pattern 640 in series using a conductive adhesive agent, thereby completing the NON-PTC type electric heating mirror 600 in which the metal-coated surface 602 is formed on the rear surface of the glass plate 601 and a heating unit is integrally formed on the metal-coated surface 602.

For example, if the NON-PTC type electric heating mirror 600 is used as a side mirror for vehicles, the electric heating mirror may constitute a side mirror assembly in company with a holder of the side mirror for vehicles through an insert molding process.

Herebelow, an eighth embodiment of the present invention will be also illustrated in detail with reference to FIGS. 11 and 12.

Comparing a method for manufacturing a NON-PTC type electric heating mirror according to the eighth embodiment with the method for manufacturing the NON-PTC type electric heating mirror according to the seventh embodiment, processes of forming the cover layer pattern 630 and the electrode pattern 640 are different from those of the seventh embodiment.

To begin with, as illustrated in A and B of FIG. 11, after forming the insulating layer 620 on the passivation layer 610 which is formed over the mirror 600, a protection jig (not shown) is disposed on the top surface of the insulating layer 620 so as to partially cover the top surface of the insulating layer 620 with a cover layer pattern which is identical in shape to the cover layer pattern 630 of the seventh embodiment. Accordingly, it is possible to form the cover layer pattern 330 on the top surface of the insulating layer 620 without using the water-soluble metalize resist ink, which is significantly different from the seventh embodiment.

After forming the cover layer pattern 630 on the predetermined portion of the insulating layer 620 by means of the protection jig, any of copper, silver and gold is plated or deposited on a predetermined region 621 of the insulating layer 620 which is not covered with the cove layer pattern 330 to thereby form a specific electrode pattern 640 (see C of FIG. 11). During this process, the shape of the electrode pattern 640 is determined by cover layer pattern formed by the protection jig, wherein the cover layer pattern may be variously modified for the sake of manufacturing convenience.

After forming the specific electrode pattern 640, the protection jig is removed from the insulating layer 620 (see D of FIG. 11). Thus, the top surface of the insulating layer 620 is divided into a region where the electrode pattern 640 is formed and the region 622 where the electrode pattern 640 is not formed.

Thereafter, a passivation layer of polyester or the like is printed/dried or deposited on both the electrode pattern 640 and the region 622 of the insulating layer 620 where the electrode pattern 640 is not formed. Afterwards, the resultant structure is dried thereby manufacturing the electric heating mirror without a current input terminal (see E of FIG. 11).

Finally, referring to FIG. 12, a current input terminal 641 and 642 is connected to a predetermined portion of the electrode pattern 640 in series using a conductive adhesive agent, thereby completing the NON-PTC type electric heating mirror 600 in which the metal-coated surface 602 is formed on the rear surface of the glass plate 601 and a heating unit is integrally formed on the metal-coated surface 602.

For instance, if the NON-PTC type electric heating mirror 600 is used as a side mirror for vehicles, the electric heating mirror may constitute a side mirror assembly in company with a holder of the side mirror for vehicles through an insert molding process.

According to the present invention, there are lots of advantageous merits below.

First, the typical etching process may be omitted and further the manufacturing process may be simplified because the glass plate itself may be used as the insulating layer in the mirror.

Second, since neither the alkali aqueous solution for removing the etching resist nor the typical etching agent is used in the present invention, the manufacturing cost is remarkably reduced.

Third, the environmental pollutant such as aluminum, hydrochloric acid, sodium hydroxide, etc, is not produced at all.

Fourth, because hydrochloric acid or alkali component does not remain in the plane heater, it is possible to perfectly overcome the conventional problem that the durability of the conventional plane heater is degraded.

Fifth, since the electrode pattern of the specific shape is directly printed on the top surface of the insulating layer or the glass plate using the conductive paste such as carbon paste, aluminum paste, copper paste, silver paste, gold paste, or the like, instead of the aluminum foil which is a cause of the partial damage during the etching process, the electrode pattern is not damaged in comparison with the conventional, and thus, there is no flame during the heating operation of the plane heater.

It will be apparent to those skilled in the art that various modifications and variations can be made in the present invention. Thus, it is intended that the present invention covers the modifications and variations of this invention provided they come within the scope of the appended claims and their equivalents.

1-5. (canceled)

6. A method for manufacturing an electric heating mirror, the method comprising:
printing an electrode pattern of a predetermined shape on a rear surface of a glass plate of a mirror, and drying it, wherein a metal-coated surface is formed on a front surface of the glass plate;
forming a passivation layer on both the electrode pattern and a region of a rear surface of the glass plate where the electrode pattern is not formed by any of printing, coating and deposition process; and
connecting a current input terminal to the electrode pattern in series using a conductive adhesive agent.

7-9. (canceled)
